(19) United States
(12) Patent Application Publication
(10) Pub. No.: US 2017/0133516 A1
(43) Pub. Date: May 11, 2017

(54) ARRAY SUBSTRATE AND METHOD FOR MANUFACTURING THE ARRAY SUBSTRATE AND DISPLAY PANEL

(71) Applicant: EVERDISPLAY OPTRONICS (SHANGHAI) LIMITED, SHANGHAI (CN)

(72) Inventors: Dong REN, SHANGHAI (CN); CHAHG-HAN CHIANG, SHANGHAI (CN); CHENGCHE LEE, SHANGHAI (CN); Kai HAN, SHANGHAI (CN)

(73) Assignee: EVERDISPLAY OPTRONICS (SHANGHAI) LIMITED, SHANGHAI (CN)

(21) Appl. No.: 15/273,939

(22) Filed: Sep. 23, 2016

(30) Foreign Application Priority Data
Nov. 9, 2015 (CN) 201510755111.8
May 13, 2016 (CN) 201610319258.7

(51) Int. Cl. H01L 29/786; H01L 27/12

(52) U.S. Cl. CPC H01L 29/78696; H01L 27/1222; H01L 27/124; H01L 27/1218; H01L 27/1285; H01L 29/78675; H01L 29/78678; H01L 27/3262

(57) ABSTRACT

The present disclosure relates to an array substrate, a method for manufacturing the array substrate and a display panel. The array substrate includes: a substrate; a poly-silicon thin film disposed on the substrate and including grains arranged along a first direction and a second direction, wherein grain boundaries of the grains extend along the first direction and the second direction; and a plurality of thin film transistors each including a channel formed by the poly-silicon thin film, wherein the channel includes a plurality of intersecting channel portions, each of which extends along a direction that neither perpendicular to nor parallel with the first or second direction.

### CROSS-REFERENCE TO RELATED APPLICATIONS

This application claims priority to Chinese Patent Application No. 201510755111.8, filed on Nov. 9, 2015 and Chinese Patent Application No. 201610319258.7, filed on May 13, 2016, the entire contents of which are incorporated herein by reference.

### TECHNICAL FIELD

The present disclosure generally relates to display technologies, and more particularly to an array substrate, a method for manufacturing the array substrate and a display panel having the array substrate.

### BACKGROUND

Existing display panels such as OLED and LCD display devices usually use Thin Film Transistors (TFTs) to control on and off of light emitting units. In order to prepare TFTs in a display panel, a poly-silicon thin film is formed on a substrate. The poly-silicon thin film serves as the active layer of each TFT so that the TFTs can have a switching function. Currently, Excimer Laser Annealing (ELA) is mainstream technology for preparing poly-silicon thin films. The ELA technology uses laser beam to scan an amorphous silicon layer to make the amorphous silicon layer to crystalize and thereby become a poly-silicon thin film. However, the crystallization of amorphous silicon layers using the ELA technology usually has an orientation characteristic, and grain boundaries along different directions are different in size.

FIG. 1 is a schematic diagram showing a poly-silicon thin film 130 formed by a Y-direction scanning using the ELA technology. The poly-silicon thin film 130 includes a plurality of grains 131 arranged along the X direction and Y direction. The boundaries of the grains 131 form grain boundaries 132. In other words, the grain boundaries 132 extend along the X and Y directions. Because of the anisotropy in poly-silicon growth, the numbers of the grain boundaries 132 oriented in different directions are different and their roughness are different, too. For example, in an example of FIG. 1, the ELA technology is used to perform scanning along the Y direction, and the roughness of the grain boundaries of the formed poly-silicon thin film 130 along the Y direction is greater than the roughness of the grain boundaries of the formed poly-silicon thin film 130 along the X direction. If the ELA technology is used to perform scanning along the X direction, the roughness of the grain boundaries of the formed poly-silicon thin film 130 along the X direction is greater than the roughness of the grain boundaries of the formed poly-silicon thin film 130 along the Y direction. In addition, because of the anisotropy in poly-silicon growth, the current flowing through the poly-silicon thin film along the X direction passes more grain boundaries than the current flowing through the poly-silicon thin film along the Y direction. As a result, display effects of light emitting elements are influenced. FIG. 2 is a schematic diagram showing a poly-silicon thin film formed by an X-direction scanning using the ELA technology. In this poly-silicon thin film, difference in the currents flowing through the poly-silicon thin film along the X and Y directions also exists.

In conventional technologies, when TFTs are prepared, the channel of each TFT is provided along the X direction or the Y direction. Thus, when there are currents flowing through the channel, current difference occurs because of differences in the numbers and sizes of the grain boundaries when the currents flow through the channel along the X and Y directions as well as the roughness of the poly-silicon thin film. Consequently, after light emitting elements are turned on, horizontal or vertical linear mura may occur.

### SUMMARY

Aiming at the defects in conventional technologies, embodiments of the present disclosure provide a display panel, an array substrate and a method for manufacturing the array substrate, which are capable of improving uniformity of current flowing through a single channel by modifying the orientations of grain boundaries and the channel.

According to an aspect of embodiments of the present disclosure, there is provided an array substrate, including:

a substrate;

a poly-silicon thin film disposed on the substrate and including grains arranged along a first direction and a second direction, wherein grain boundaries of the grains extend along the first direction and the second direction; and

a plurality of thin film transistors each including a channel formed by the poly-silicon thin film, wherein the channel includes a plurality of intersecting channel portions, each of which extends along a direction that is neither perpendicular to nor parallel with the first or second direction.

According to an embodiment, two of the intersecting channel portions in the channel extend along directions which are perpendicular to each other.

According to an embodiment, the substrate has a rectangular shape and has two first sides which are parallel with each other and two second sides which are perpendicular to the first sides, respectively, and

wherein the channel includes:

at least one first channel portion in parallel with the first sides; and

at least one second channel portion in parallel with the second sides.

According to an embodiment, an angle between each of the channel portions and the first direction ranges from 5 degrees to 85 degrees.

According to an embodiment, angles between individual channel portions and the first direction are equal to each other.

According to an embodiment, the channel is any one of an S-shaped channel, a V-shaped channel, an N-shaped channel and a W-shaped channel.

According to an embodiment, each of the thin film transistors is a top-gate thin film transistor or a bottom-gate thin film transistor.

According to an embodiment, each of the thin film transistors includes a gate, a source and a drain, and the source and the drain are electrically connected with the channel.

According to an embodiment, the first direction is perpendicular to the second direction.

According to another aspect of embodiments of the present disclosure, there is provided a display panel, including the array substrate as mentioned above.

According to another aspect of embodiments of the present disclosure, there is provided a method for manufacturing an array, including:

providing a substrate;

forming an amorphous silicon layer on the substrate, wherein the substrate has a rectangular shape and has two first sides which are parallel with each other and two second sides which are perpendicular to the first sides, respectively;

using an excimer laser annealing process, scanning the amorphous silicon layer along a second direction to make the amorphous silicon layer become a poly-silicon thin film, wherein the poly-silicon thin film includes grains arranged along a first direction and a second direction, grain boundaries of the grains extend along the second direction and a first direction which is perpendicular to the second direction, and there is a first angle between the first direction and each of the first sides; and

forming a plurality of thin film transistors each including a channel formed by the poly-silicon thin film, wherein the channel includes at least one first channel portion in parallel with the first sides and at least one second channel portion in parallel with the second sides.

According to an embodiment, before the scanning of the amorphous silicon layer along the second direction, the method further includes:

rotating a carrier for carrying the substrate by the first angle to make the first angle formed between the first direction and each of the first sides.

According to an embodiment, before the scanning of the amorphous silicon layer along the second direction, the method further includes:

rotating a laser beam generation device used in the excimer laser annealing process by the first angle to make the first angle formed between the first direction and each of the first sides.

According to an embodiment, the forming of the amorphous silicon layer on the substrate includes:

depositing amorphous silicon and performing high temperature dehydrogenization.

According to an embodiment, the forming of the plurality of thin film transistors includes:

using a mask having a plurality of openings, etching the poly-silicon thin film to form a plurality of channels.

According to an embodiment, the first angle ranges from 5 degrees to 85 degrees.

As compared with conventional technologies, each TFT in the technical solutions of the present disclosure has a channel, and there is an angle between each of channel portions in the channel and each of the extending direction of grain boundaries, and thus uniformity of current flowing through a single channel can be improved. Further, in the present disclosure, an amorphous silicon layer is scanned using the ELA technology along a second direction and there is an angle between the second direction and a side of a substrate, and thus the extending directions of grain boundaries are different from (the extending directions of) the channel of each TFT. By the structures and methods provided by the present disclosure, difference or nonuniformity of current flowing through a single TFT can be reduced, and thus performance of TFTs can be improved and horizontal or vertical linear mura on display panels due to current differences can be avoided.

### BRIEF DESCRIPTION OF THE DRAWINGS

The above and other features and advantages of the present disclosure will become clearer from the description of exemplary embodiments with reference to drawings.

FIG. 1 is a schematic diagram showing a poly-silicon thin film formed by a Y-direction scanning using an ELA technology in conventional technologies.

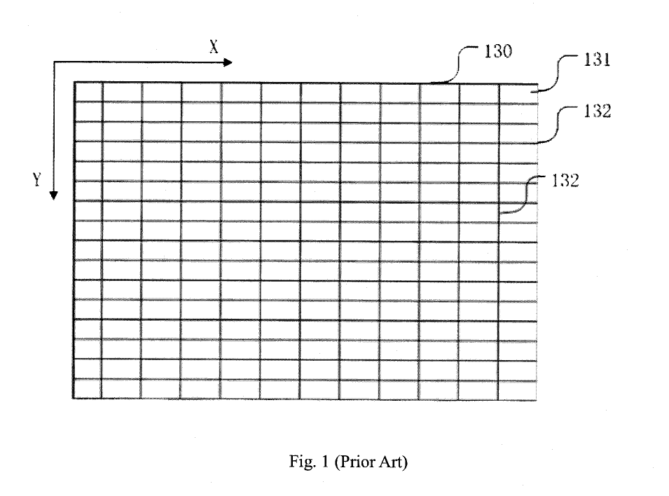

FIG. 2 is a schematic diagram showing a poly-silicon thin film formed by an X-direction scanning using the ELA technology in conventional technologies.

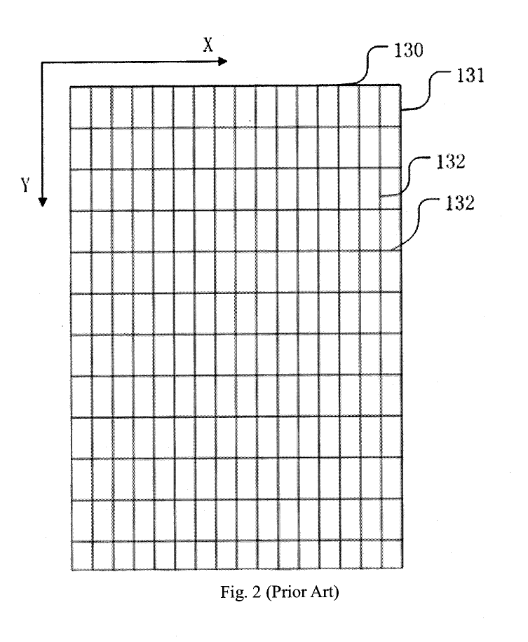

FIG. 3A is a schematic diagram showing an array substrate according to an embodiment of the present disclosure.

FIG. 3B is a schematic diagram showing another array substrate according to an embodiment of the present disclosure.

FIG. 4 illustratively shows an S-shaped channel according to an embodiment of the present disclosure.

FIG. 5 illustratively shows a V-shaped channel according to an embodiment of the present disclosure.

FIG. 6 is a cross-sectional view of a display panel according to an embodiment of the present disclosure.

FIG. 7 is a schematic diagram showing a structure of a poly-silicon layer after an amorphous silicon layer is scanned using the ELA technology during manufacturing of a display panel according to an embodiment of the present disclosure.

### DETAILED DESCRIPTION

Now, exemplary implementations will be described more comprehensively with reference to the accompanying drawings. However, the exemplary implementations may be carried out in various manners, and should not be interpreted as being limited to the implementations set forth herein; instead, providing these implementations will make the present disclosure more comprehensive and complete and will fully convey the conception of the exemplary implementations to the ordinary skills in this art. Throughout the drawings, the like reference numbers refer to the same or the like structures, and repeated descriptions will be omitted.

The features, structures or characteristics described herein may be combined in one or more embodiments in any suitable manner. In the following descriptions, many specific details are provided to facilitate sufficient understanding of the embodiments of the present disclosure. However, one of ordinary skills in this art will appreciate that the technical solutions in the present disclosure may be practiced without one or more of the specific details, or by employing other methods, components, materials and so on. In other conditions, well-known structures, materials or operations are not shown or described in detail so as to avoid confusion of respective aspects of the present disclosure.

The drawings are presented herein only for the purpose of illustrating relative positional relationships, and sizes of elements throughout the drawings do not represent actual sizes or proportional relations.

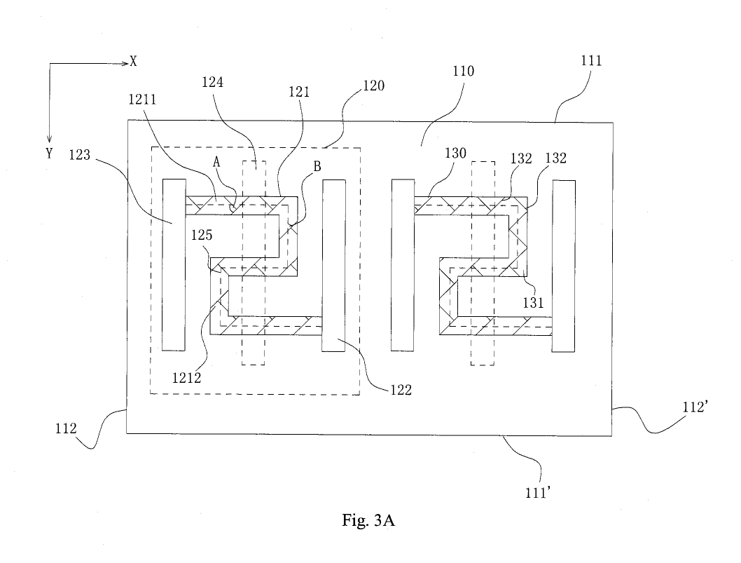

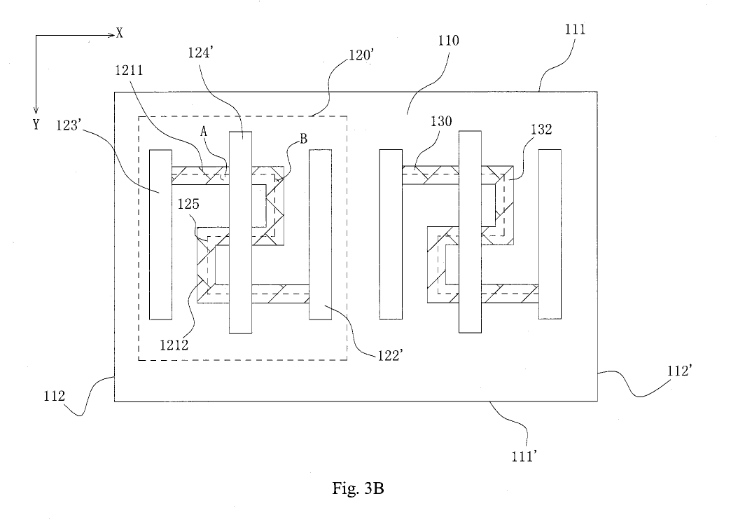

In order to solve the problem of differences (or nonuniformity) in current flowing through a single channel of a TFT in conventional technologies, embodiments of the present disclosure provide a display panel having TFTs and a method for manufacturing the same. The display panel and the method for manufacturing the same will be described below with reference to FIGS. 3 to 8.

### First Embodiment

FIG. 3A is a schematic diagram showing an array substrate according to an embodiment of the present disclosure. The array substrate includes a substrate 110, a poly-silicon thin film on the substrate 110 and a plurality of TFTs 120. The substrate 110 can be a glass substrate or a substrate formed by resin composite materials. In the embodiment as shown in FIG. 3A, the substrate 110 can have a rectangular shape for example. The substrate 110 includes two first sides 111 and 111′ which are parallel with each other and two second sides 112 and 112′ which are perpendicular to the first sides 111 and 111′, respectively. The first sides 111 and 111′ are parallel with the X direction, and the second sides 112 and 112′ are parallel with the Y direction.

A poly-silicon thin film 130 is formed on the substrate 110 using an ELA technology so that a plurality of grains 131 are formed on the substrate 110. Specifically, scanning is performed along a second direction using the ELA technology to form a plurality of crystallization regions where the grains 131 arranged along a first direction and the second direction are formed due to different crystallinities. The boundaries of the grains 131 form the grain boundaries 132 which extend along the first and second directions. In an embodiment of the present disclosure, the first direction is perpendicular to the second direction.

In an embodiment of the present disclosure, after scanning is performed along the second direction using the ELA technology, the grain boundaries 132 extending along the first and second directions are formed. A first angle, which is greater than 0 degree and smaller than 90 degrees, is formed between the first direction and the first side 111 or 111′ of the substrate 110.

Each of the TFTs 120 may be a top-gate TFT or a bottom-gate TFT. In the example in FIG. 3A, the TFTs 120 are bottom-gate TFTs. Specifically, each of the TFTs 120 includes a gate 124, a source 123, a drain 122 and a channel 121 formed in the poly-silicon thin film 130. In the embodiment as shown in FIG. 3A, the source 123, the gate 124 and the drain 122 are arranged along the X direction, and the gate 124, the source 123 and the drain 122 extend along a direction in parallel with the Y direction.

Specifically, as shown in FIG. 3A, in an embodiment of the present disclosure, each channel 121 includes three first channel portions 1211 extending along a direction in parallel with the X direction and two second channel portions 1212 extending along a direction in parallel with the Y direction. The three first channel portions 1211 and the two channel portions 1212 intersect with each other to form an “S”. Since the first channel portions 1211 are parallel with the X direction, there is an angle A, which is equal to the first angle, between the extending direction of the first channel portions 1211 and each of the grain boundaries 132 extending along the first direction. In other words, the grain boundaries 132 extending along the first direction are neither parallel with nor perpendicular to the extending direction of the first channel portions 1211. In the embodiment as shown in FIG. 3A, the extending direction of the first channel portions 1211 is perpendicular to the extending direction of the second channel portions 1212, and thus there is an angle B, which is a complementary angle of the angle A, between the extending direction of the second channel portions 1212 and each of the grain boundaries 132 extending along the first direction. In other words, the grain boundaries 132 extending along the first direction are neither parallel with nor perpendicular to the extending direction of the second channel portions 1212. In an embodiment, the angles A and B can range from 5 to 85 degrees.

It should be noted that the first direction is perpendicular to the second direction in embodiments of the present disclosure, and thus there is an angle, which is equal to the first angle, between each of the second sides 112 and 112′ of the substrate 110 and each of the grain boundaries 132 extending along the second direction. Then, there is an angle, which is equal to the angle A, between the extending direction of the second channel portions 1212 and each of the grain boundaries 132 extending along the second direction, and there is an angle, which is equal to the angle B, between the extending direction of the first channel portions 1211 and each of the grain boundaries 132 extending along the second direction. It can be seen that the extending directions of the first channel portions 1211 and the second channel portions 1212 are neither perpendicular to nor parallel with the grain boundaries 132 extending along the first and second directions.

When high levels are applied on the drain 122 and the gate 124 and the voltage Vgs between the gate 124 and the source 123 is greater than or equal to a threshold voltage Vth, migration of electrons in the channel 121 close to the gate 124 occurs between the drain 122 and the source 123 to form channel current. The direction of current 125 is consistent with the extending direction of the channel 121.

As shown in FIG. 3A, the channel current 125 flowing through the channel portions of the channel 121 passes the grain boundaries 132 extending along the first and second directions, and the extending directions of the first channel portions 1211 and the second channel portions 1212 in each channel 121 are neither perpendicular to nor parallel with the grain boundaries extending the first and second directions; thus, in one channel 121, the differences between the number and sizes of the grain boundaries 132 that the current 125 flowing through the first channel portions 1211 passes and the number and sizes of the grain boundaries 132 that the current 125 flowing through the second channel portions 1212 passes can be remarkably reduced, and thereby the uniformity between the current 125 flowing through the first channel portions 1211 and the current 125 flowing through the second channels 1212 can be improved.

In order to further reduce the differences between the number and sizes of the grain boundaries 132 that the current 125 flowing through the first channel portions 1211 passes and the number and sizes of the grain boundaries 132 that the current 125 flowing through the second channel portions 1212 passes, the angle A and the angle B can be equal to each other. For example, in the embodiment as shown in FIG. 3A, the angles A and B can be 45 degrees.

It should be noted that in the embodiment as shown in FIG. 3A, the extending direction of the first channel portions 1211 is perpendicular to the extending direction of the second channel portions 1212, and is parallel with the first sides 111 and 111′ of the rectangular substrate 110. In some modified embodiments of the present disclosure, the extending direction of the first channel portions 1211 is not perpendicular to the extending direction of the second channel portions 1212 in the channel 121, or the first channel portions 1211 are not parallel with the first sides 111 and 111′ of the rectangular substrate 110, and detailed descriptions are not elaborated here.

### Second Embodiment

FIG. 3B is a schematic diagram showing another array substrate according to an embodiment of the present disclosure. The array substrate in FIG. 3B is similar to that in FIG. 3A and the difference between the two is that the TFTs 120′ in FIG. 3B are top-gate TFTs. As shown in FIG. 3B, a gate is disposed over the channel 121. Because the extending directions of the first channel portions 1211 and the second channel portions 1212 are neither parallel with nor perpendicular to the grain boundaries 132 extending along the first and second directions, the embodiment in FIG. 3B can arrive at the same technical effects as FIG. 3B, and repeated descriptions are omitted here.

### Third Embodiment

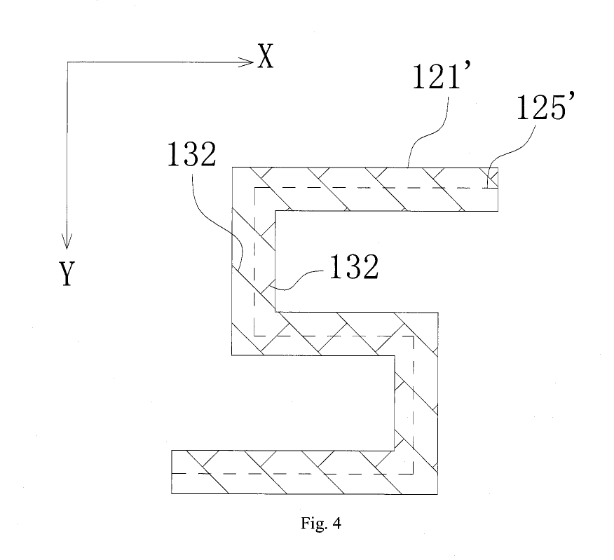

FIG. 4 illustratively shows a channel 121′. The channel 121′ has a structure similar to that of the channel 121 in FIGS. 3A and 3B, i.e., the channel 121′ is an S-shaped channel, too. The difference between the channel 121′ in FIG. 4 and the channel 121 in FIGS. 3A and 3B is that the channel 121′ is a mirror symmetrical one of the channel 121. In other words, a normal S-shaped channel, a reversed S-shaped channel, or a flipped S-shaped channel all can be considered as an S-shaped channel

The channel 121′ in FIG. 4 is a mirror symmetrical one of the channel 121, and thus the flowing direction of the channel current 125′ and the flowing direction of the channel current 125 in FIGS. 3A and 3B are mirror symmetrical, too.

### Fourth Embodiment

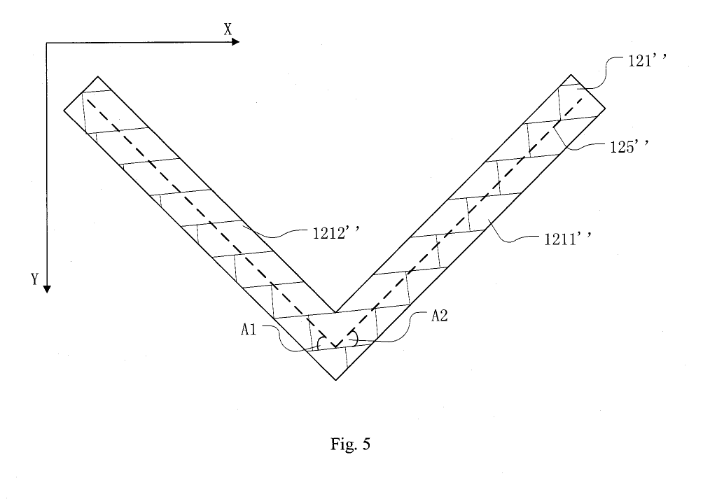

FIG. 5 illustratively shows another channel 121″. The channel 121″ is a V-shaped channel, including two channel portions, i.e., 1211″ and 1212″. The flowing direction of the channel current 125″ is consistent with the shape of the channel 121″, i.e., the current flows along a V shape. In other words, the channel 125″ flows along the extending directions of the channel portions 1211″ and 1212″. Thus, in the embodiment, the angles between the flowing direction of the channel current 125″ and the grain boundaries extending along the first direction are used to described the angels between the extending directions of the two channel portions 1211″ and 1212″ and the grain boundaries 132″ extending along the first direction. Specifically, in the embodiment, the angles A1 and A2 between the flowing directions of the V-shaped channel current 125″ and the grain boundaries 132″ extending along the first direction are not equal to each other. The angles A1 and A2 may be any one between 5 and 85 degrees. In an embodiment, the angle A1 or A2 may be 45 degrees. In some modified embodiments, the angles A1 and A2 can be equal to each other. For example, the current 125″ flows through the channel portion 1211″ along a direction perpendicular to the direction along which the current 125″ flows through the channel portion 1212″, and the angles A1 and A2 are not equal to 45 degrees.

The channel provided in the present disclosure has been described using the above third and fourth embodiments, and one of ordinary skill in this art can conceive other types of channel, for example, an N-shaped channel or a W-shaped channel, and all such modifications to the shape of the channel should be deemed falling within the scope of the present disclosure.

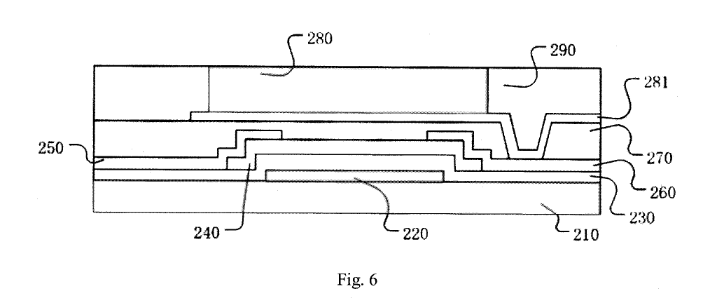

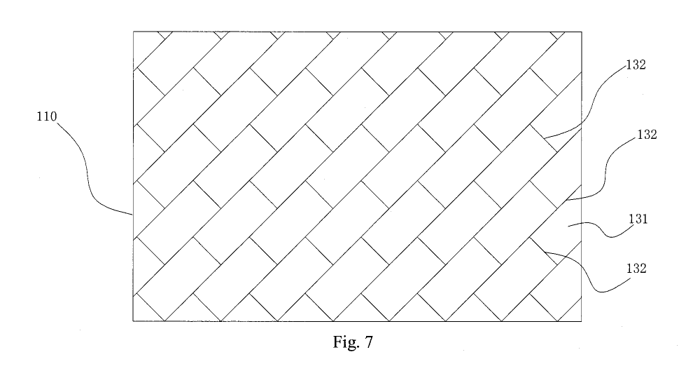

FIG. 6 is a cross-sectional display panel according to an embodiment of the present disclosure, and FIG. 7 is a schematic diagram showing a structure of a poly-silicon layer after an amorphous silicon layer is scanned using the ELA technology during manufacturing of the display panel as shown in FIG. 6. For example, the display panel in FIG. 6 has a bottom-gate structure. The method for manufacturing the array substrate and the display panel according to embodiments of the present disclosure will be described below. The method can include the following steps.

A substrate 210 is provided. For example, the substrate 210 is a rectangular substrate which includes two first sides that are parallel with each other and two second sides which are perpendicular to the first sides, respectively.

A gate 220 is formed on the substrate 210.

A gate insulation layer 230 is formed on the gate 220.

An amorphous silicon layer is formed on the gate insulation layer 230. Specifically, in some embodiments of the present disclosure, the forming of the amorphous silicon layer on the substrate can include depositing amorphous silicon and performing high temperature dehydrogenization.

Using the ELA technology, the amorphous silicon layer is scanned to make the amorphous silicon layer become a poly-silicon thin film. Specifically, scanning is performed using the ELA technology along the second direction to form the poly-silicon thin film. The poly-silicon thin film includes grains 131 arranged along the first direction and the second direction, and edges of the grains 131 form a plurality of grain boundaries 132 extending along the first direction and the second direction. In an embodiment of the present disclosure, the first direction is perpendicular to the second direction. A first angle, which is greater than 0 degree and smaller than 90 degrees, is formed between the first direction and one of the first sides. The same angle is formed between the second direction and one of the second sides of the substrate. For example, the first angle ranges from 5 to 85 degrees. An example of the structure formed after the above steps are completed can be found in FIG. 7.

Further, in order to realize that one of the first sides of the substrate is in the first angle greater than 0 degree and smaller than 90 degree with respect to the first direction, in some embodiments of the present disclosure, before the scanning of the amorphous silicon layer along the second direction, the method can further include: rotating a carrier for carrying the substrate by the first angle. By rotating the carrier for carrying the substrate, the first angle can be formed between the first direction and each of the first sides of the substrate. Alternatively, in some other embodiments, before the scanning of the amorphous silicon layer along the second direction, the method can further include: rotating a laser beam generation device used in the ELA process by the first angle. By rotating the laser beam generation device, the first angle can be formed between the first direction and each of the first sides.

After formation of the poly-silicon thin film, a plurality of TFTs are formed. Each of the TFTs includes a channel formed by the poly-silicon thin film. The channel includes at least one first channel portion in parallel with the first sides and at least one second channel portion in parallel with the second sides. For example, using a mask having a plurality of openings, the poly-silicon thin film can be etched to form the channel.

After forming of the channel 240 by etching the poly-silicon thin film, a source 250 and a drain 260 are formed on the channel 240.

A planarization layer 270 is formed on the source 250 and the drain 260.

An opening is formed in the planarization layer 270 to enable the connection between a cathode 281 of each display element 280 and the drain 260.

Then, the display elements 280 are formed. The cathode 281 of each display element 280 is in contact with the drain 260 via the opening

And, a pixel defining layer 290 is formed between any two adjacent ones of the display elements 280.

The above is an illustrative method for manufacturing a display panel having bottom-gate TFTs. However, one of ordinary skill in this art can conceive many modified examples according to different display elements and different TFT structures. For example, some steps can be omitted or added if needed, and specification descriptions are not elaborated here.

As compared with conventional technologies, each TFT in the technical solutions of the present disclosure has a channel, and there is an angle between each of channel portions in the channel and each of the extending direction of grain boundaries, and thus uniformity of current flowing through a single channel can be improved. Further, in the present disclosure, an amorphous silicon layer is scanned using the ELA technology along a second direction and there is an angle between the second direction and a side of a substrate, and thus the extending directions of grain boundaries are different from (the extending directions of) the channel of each TFT. By the structures and methods provided by the present disclosure, difference or nonuniformity of current flowing through a single TFT can be reduced, and thus performance of TFTs can be improved and horizontal or vertical linear mura on display panels due to current differences can be avoided.

Exemplary embodiments of the present disclosure are shows and described above. However, it should be understood that the present disclosure is not limited to the above disclosed implementations. Instead, the present disclosure is intended to encompass various modifications and equivalent replacements within the scope of the appended claims.

What is claimed is:

1. An array substrate, comprising:
a substrate;
a poly-silicon thin film disposed on the substrate and comprising grains arranged along a first direction and a second direction, wherein grain boundaries of the grains extend along the first direction and the second direction; and
a plurality of thin film transistors each comprising a channel formed by the poly-silicon thin film, wherein the channel comprises a plurality of intersecting channel portions, each of which extends along a direction that neither perpendicular to nor parallel with the first or second direction.

2. The array substrate according to claim 1, wherein two of the intersecting channel portions in the channel extend along directions which are perpendicular to each other.

3. The array substrate according to claim 2, wherein the substrate has a rectangular shape and has two first sides which are parallel with each other and two second sides which are perpendicular to the first sides, respectively, and
wherein the channel comprises:
at least one first channel portion in parallel with the first sides; and
at least one second channel portion in parallel with the second sides.

4. The array substrate according to claim 1, wherein an angle between each of the channel portions and the first direction ranges from 5 degrees to 85 degrees.

5. The array substrate according to claim 4, wherein angles between individual channel portions and the first direction are equal to each other.

6. The array substrate according to claim 1, wherein the channel is any one of an S-shaped channel, a V-shaped channel, an N-shaped channel and a W-shaped channel

7. The array substrate according to claim 1, wherein each of the thin film transistors is a top-gate thin film transistor or a bottom-gate thin film transistor.

8. The array substrate according to claim 7, wherein each of the thin film transistors comprises a gate, a source and a drain, and the source and the drain are electrically connected with the channel.

9. The array substrate according to claim 1, wherein the first direction is perpendicular to the second direction.

10. A display panel, comprising an array substrate, wherein the array substrate comprises:
a substrate;
a poly-silicon thin film disposed on the substrate and comprising grains arranged along a first direction and a second direction, wherein grain boundaries of the grains extend along the first direction and the second direction; and
a plurality of thin film transistors each comprising a channel formed by the poly-silicon thin film, wherein the channel comprises a plurality of intersecting channel portions, each of which extends along a direction that neither perpendicular to nor parallel with the first or second direction.

11. The display panel according to claim 10, wherein two of the intersecting channel portions in the channel extend along directions which are perpendicular to each other.

12. The array substrate according to claim 11, wherein the substrate has a rectangular shape and has two first sides which are parallel with each other and two second sides which are perpendicular to the first sides, respectively, and
wherein the channel comprises:
at least one first channel portion in parallel with the first sides; and
at least one second channel portion in parallel with the second sides.

13. The display panel according to claim 10, wherein an angle between each of the channel portions and the first direction ranges from 5 degrees to 85 degrees.

14. The array substrate according to claim 13, wherein angles between individual channel portions and the first direction are equal to each other.

15. A method for manufacturing an array substrate, comprising:
providing a substrate;
forming an amorphous silicon layer on the substrate, wherein the substrate has a rectangular shape and has two first sides which are parallel with each other and two second sides which are perpendicular to the first sides, respectively;
using an excimer laser annealing process, scanning the amorphous silicon layer along a second direction to make the amorphous silicon layer become a poly-silicon thin film, wherein the poly-silicon thin film comprises grains arranged along a first direction and a second direction, grain boundaries of the grains extend along the second direction and a first direction which is perpendicular to the second direction, and there is a first angle between the first direction and each of the first sides; and
forming a plurality of thin film transistors each comprising a channel formed by the poly-silicon thin film, wherein the channel comprises at least one first channel portion in parallel with the first sides and at least one second channel portion in parallel with the second sides.

16. The method according to claim 15, before the scanning of the amorphous silicon layer along the second direction, the method further comprises:
rotating a carrier for carrying the substrate by the first angle to make the first angle formed between the first direction and each of the first sides.

17. The method according to claim 15, wherein before the scanning of the amorphous silicon layer along the second direction, the method further comprises:
rotating a laser beam generation device used in the excimer laser annealing process by the first angle to make the first angle formed between the first direction and each of the first sides.

18. The method according to claim 15, wherein the forming of the amorphous silicon layer on the substrate comprises:
depositing amorphous silicon and performing high temperature dehydrogenization.

19. The method according to claim 15, wherein the forming of the plurality of thin film transistors comprises:
using a mask having a plurality of openings, etching the poly-silicon thin film to form the channel.

20. The method according to claims 15, wherein the first angle ranges from 5 degrees to 85 degrees.
